(19) United States
(12) Patent Application Publication
(10) Pub. No.: US 2025/0261483 A1
(43) Pub. Date: Aug. 14, 2025

(54) LIGHT-EMITTING DRIVING DEVICE PACKAGE APPARATUS, METHOD OF MANUFACTURING THE SAME, AND BONDING WAFER

(71) Applicant: Global Technologies Co., LTD, Hwaseong-si Gyeonggi-do (KR)

(72) Inventors: Min Seon KIM, Hwaseong-si Gyeonggi-do (KR); Seung Hyun OH, Gwangju-si Gyeonggi-do (KR); Jung Hyun PARK, Osan-si Gyeonggi-do (KR)

(73) Assignee: Global Technologies Co., LTD, Hwaseong-si Gyeonggi-do (KR)

(21) Appl. No.: 19/052,959

(22) Filed: Feb. 13, 2025

(30) Foreign Application Priority Data
Feb. 13, 2024 (KR) 10-2024-0020197

(51) Int. Cl. H10H 20/819; H01L 25/16; H10H 20/01

(52) U.S. Cl. CPC H10H 20/819; H01L 25/167; H10H 20/018

(57) ABSTRACT

Provided are a light-emitting driving device package apparatus capable of preventing warping or distortion caused by the difference in thermal expansion coefficient when a sapphire wafer and a silicon wafer are bonded together, a method of manufacturing the same, and a bonding wafer, the light-emitting driving device package apparatus including a light-emitting device made of sapphire material and including a light-emitter for outputting light, and a driving device bonded to the light-emitting device, made of silicon material, and including a driving circuit for applying a driving signal to the light-emitter to drive the light-emitter, wherein thermal deformation prevention holes are formed in at least portions of the light-emitting device or the driving device to prevent warping or distortion caused by a difference in thermal expansion coefficient between sapphire material and silicon material.

### CROSS-REFERENCE TO RELATED PATENT APPLICATION

The present application claims priority under 35 U.S.C. § 119 (a) to Korean Patent Application No. 10-2024-0020197, filed on Feb. 13, 2024, in the Korean Intellectual Property Office, the entire contents of which application is incorporated herein by reference.

### BACKGROUND OF THE DISCLOSURE

### 1. Technical Field

The present disclosure relates to a light-emitting driving device package apparatus, a method of manufacturing the same, and a bonding wafer, and more particularly, to a light-emitting driving device package apparatus capable of preventing warping or distortion caused by the difference in thermal expansion coefficient when a sapphire wafer and a silicon wafer are bonded together, a method of manufacturing the same, and a bonding wafer.

### 2. Description of the Related Art

When a sapphire wafer with light-emitting devices such as micro-light-emitting diodes (LEDs) on its surface is wafer-to-wafer bonded to a silicon wafer with driving devices such as driving-integrated circuits (ICs) on its surface, warping or distortion occurs due to the different thermal expansion coefficients of sapphire and silicon.

The instability in bonding caused by the difference in thermal expansion coefficient becomes more frequent as the wafer size increases, and leads to issues such as cracks or temperature gradients. Thus, in general, wafers larger than 2 inches are not bondable together to cause low process yields and significant difficulties in mass production. Even when wafers are divided and bonded together in smaller sizes, the significant increase in labor and time notably decreases production capacity or makes mass production infeasible.

### SUMMARY OF THE DISCLOSURE

According to an aspect of the present disclosure, there is provided a light-emitting driving device package apparatus including a light-emitting device made of sapphire material and including a light-emitter for outputting light, and a driving device bonded to the light-emitting device, made of silicon material, and including a driving circuit for applying a driving signal to the light-emitter to drive the light-emitter, wherein thermal deformation prevention holes are formed in at least portions of the light-emitting device or the driving device to prevent warping or distortion caused by a difference in thermal expansion coefficient between sapphire material and silicon material.

According to another aspect of the present disclosure, there is provided a method of manufacturing a light-emitting driving device package apparatus, the method including (a) preparing a sapphire wafer made of sapphire material and including a plurality of light-emitting devices with light-emitters for outputting light, (b) preparing a silicon wafer made of silicon material and including a plurality of driving devices with driving circuits capable of applying driving signals to the light-emitters to drive the light-emitters, (c) bonding the sapphire wafer and the silicon wafer together, and (d) cutting the bonded sapphire wafer and silicon wafer into individual packages, wherein, in step (a) or step (b), one or more thermal deformation prevention holes are formed in at least portions of the sapphire wafer or the silicon wafer to prevent warping or distortion caused by a difference in thermal expansion coefficient between sapphire material and silicon material.

According to another aspect of the present disclosure, there is provided a bonding wafer including a wafer body made of sapphire material or silicon material, a plurality of devices provided on the wafer body and including light-emitters for outputting light, or driving circuits for applying driving signals to the light-emitters, thermal deformation prevention holes provided between the devices to prevent warping or distortion caused by thermal expansion coefficients when bonded to another wafer made of a different material, and aligners provided between the devices to align bonding positions when bonded to another wafer.

### BRIEF DESCRIPTION OF THE DRAWINGS

The above and other features and advantages of the present disclosure will become more apparent by describing in detail embodiments thereof with reference to the attached drawings in which:

FIG. 1 is an external perspective view of a light-emitting driving device package apparatus according to embodiments of the present disclosure;

FIG. 2 is a cross-sectional view cut along II-II of the light-emitting driving device package apparatus of FIG. 1;

FIG. 3 is an exploded perspective view of the light-emitting driving device package apparatus of FIG. 1;

FIG. 4 is a perspective view of a sapphire wafer for manufacturing the light-emitting driving device package apparatus of FIG. 1;

FIG. 5 is a perspective view of a silicon wafer for manufacturing the light-emitting driving device package apparatus of FIG. 1;

FIG. 6 is an enlarged perspective view showing a process of injecting underfill into the light-emitting driving device package apparatus of FIG. 1;

FIG. 7 includes cross-sectional views showing a process of preparing the sapphire wafer of the light-emitting driving device package apparatus of FIG. 4, step by step;

FIG. 8 includes cross-sectional views showing a process of preparing the silicon wafer of the light-emitting driving device package apparatus of FIG. 5, step by step;

FIG. 9 includes cross-sectional views showing a process of bonding the sapphire wafer of FIG. 4 to the silicon wafer of FIG. 5, step by step; and

FIG. 10 is a flowchart of a method of manufacturing a light-emitting driving device package apparatus, according to embodiments of the present disclosure.

### DETAILED DESCRIPTION OF THE DISCLOSURE

Hereinafter, the present disclosure will be described in detail by explaining embodiments of the disclosure with reference to the attached drawings.

The disclosure may, however, be embodied in many different forms and should not be construed as being limited to the embodiments set forth herein; rather, these embodiments are provided so that this disclosure will be thorough and complete, and will fully convey the concept of the disclosure to one of ordinary skill in the art. In the drawings, the thicknesses or sizes of layers are exaggerated for clarity and convenience of explanation.

The terminology used herein is for the purpose of describing particular embodiments and is not intended to limit the disclosure. As used herein, the singular forms “a”, “an”, and “the” are intended to include the plural forms as well, unless the context clearly indicates otherwise. It will be further understood that the terms “comprises” and/or “comprising”, when used in this specification, specify the presence of stated features, integers, steps, operations, elements, components, and/or groups thereof, but do not preclude the presence or addition of one or more other features, integers, steps, operations, elements, components, and/or groups thereof.

Embodiments of the disclosure are described herein with reference to schematic illustrations of idealized embodiments and intermediate structures) of the disclosure. As such, variations from the shapes of the illustrations as a result, for example, of manufacturing techniques and/or tolerances, are to be expected. Thus, the embodiments of the disclosure should not be construed as limited to the particular shapes of regions illustrated herein, but are to include deviations in shapes that result, for example, from manufacturing.

The present disclosure provides a light-emitting driving device package apparatus capable of preventing warping or distortion caused by the difference in thermal expansion coefficient when a sapphire wafer and a silicon wafer are bonded together, a method of manufacturing the same, and a bonding wafer. However, the above description is an example, and the scope of the present disclosure is not limited thereto.

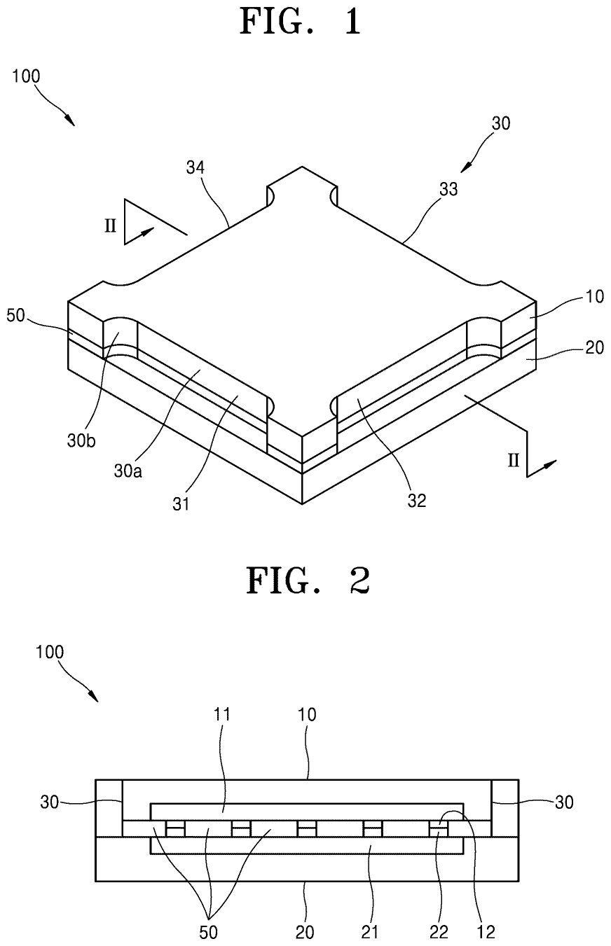

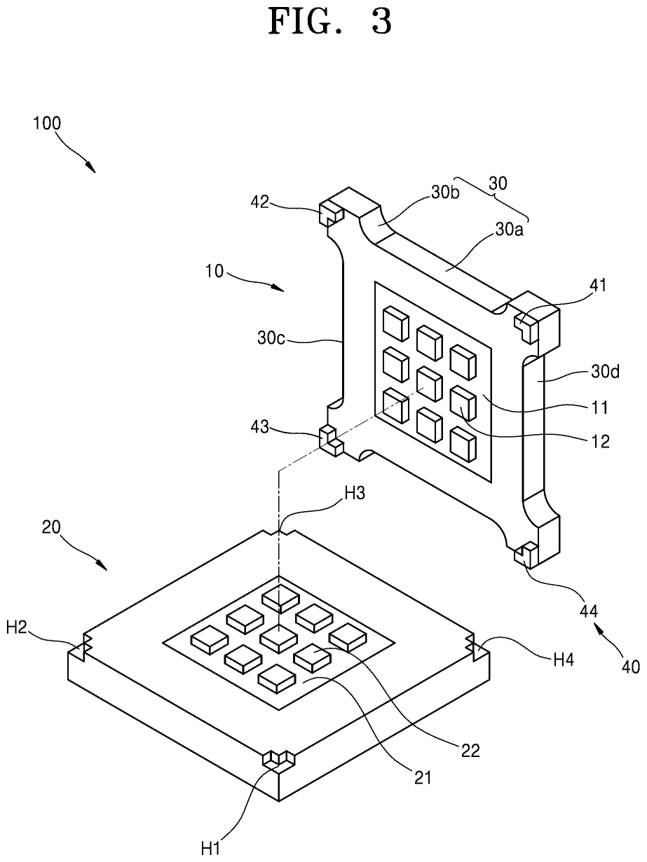

FIG. 1 is an external perspective view of a light-emitting driving device package apparatus 100 according to embodiments of the present disclosure, FIG. 2 is a cross-sectional view cut along II-II of the light-emitting driving device package apparatus 100 of FIG. 1, and FIG. 3 is an exploded perspective view of the light-emitting driving device package apparatus 100 of FIG. 1.

Initially, as shown in FIGS. 1 to 3, the light-emitting driving device package apparatus 100 according to embodiments of the present disclosure may mainly include a light-emitting device 10 and a driving device 20.

The light-emitting device 10 may be, for example, a portion provided in an overall rectangular plate shape, made of sapphire material, and including a light-emitter 11 for outputting light.

The driving device 20 may be, for example, a portion bonded to the light-emitting device 10, provided in an overall rectangular plate shape, made of silicon material, and including a driving circuit 21 for applying a driving signal to the light-emitter 11 to drive the light-emitter

Herein, the light-emitter 11 and the driving circuit 21 may include connection terminals 12 and 22 such as bumps, respectively, and the connection terminals 12 and 22 may be bonded and electrically connected to each other.

Thermal deformation prevention holes 30 may be formed in at least portions of the light-emitting device 10 to prevent warping or distortion caused by the difference in thermal expansion coefficient between sapphire material and silicon material.

However, the thermal deformation prevention holes 30 are not limited to the light-emitting device 10. For example, the thermal deformation prevention holes 30 may be formed in the driving device 20 or in both the light-emitting device 10 and the driving device 20.

For example, as shown in FIG. 1, each thermal deformation prevention hole 30 may include at least a portion of a long hole 30a extending along a side surface in a lengthwise direction to counteract lateral thermal deformation forces, and have rounded inner surfaces 30b at both ends to prevent stress concentration at the ends.

Specifically, for example, as shown in FIG. 1, to prevent thermal deformation in all forward, backward, left, and right directions, the thermal deformation prevention holes 30 may include a first long hole 31 formed in a central portion of a first side surface of the light-emitting device 10, a second long hole 32 formed in a central portion of a second side surface of the light-emitting device 10, a third long hole 33 formed in a central portion of a third side surface of the light-emitting device 10, and a fourth long hole 34 formed in a central portion of a fourth side surface of the light-emitting device 10.

The thermal deformation prevention holes 30 may be used not only to prevent thermal deformation but also to inject underfill 50.

That is, at least one of the first, second, third, and fourth long holes 31, 32, 33, and 34 may serve as an injection port 30c through which the underfill 50 is injected, and at least another one of the first, second, third, and fourth long holes 31, 32, 33, and 34 may serve as a discharge port 30d through which the underfill 50 or internal air is discharged.

Meanwhile, the light-emitting driving device package apparatus according to embodiments of the present disclosure may further include aligners 40 provided between the light-emitting device 10 and the driving device 20 and fitted to each other to align bonding positions when the light-emitting device 10 and the driving device 20 are bonded together.

For example, as shown in FIG. 3, the aligners 40 are provided to fit into alignment recesses H formed in the driving device 20. Specifically, for example, the aligners 40 may include a first alignment protrusion 41 provided on a first corner of the light-emitting device 10, a second alignment protrusion 42 provided on a second corner of the light-emitting device 10, a third alignment protrusion 43 provided on a third corner of the light-emitting device 10, and a fourth alignment protrusion 44 provided on a fourth corner of the light-emitting device 10.

To fit the aligners 40, the alignment recesses H may include, for example, a first alignment recess H1 formed in a first corner of the driving device 20, a second alignment recess H2 formed in a second corner of the driving device 20, a third alignment recess H3 formed in a third corner of the driving device 20, and a fourth alignment recess H4 formed in a fourth corner of the driving device 20.

The alignment protrusions of the aligners 40 may be L-shaped or cross-shaped, and the alignment recesses of the alignment recesses H may also be L-shaped or cross-shaped to fit the aligners 40.

However, the aligners 40 or the alignment recesses H are not limited to the illustrated shape, and may be provided in various other forms or shapes.

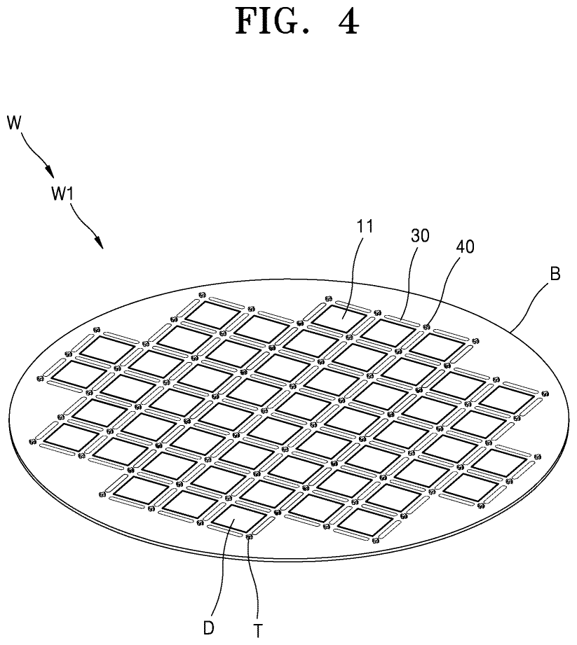

FIG. 4 is a perspective view of a sapphire wafer W1 for manufacturing the light-emitting driving device package apparatus 100 of FIG. 1.

As shown in FIG. 4, as a bonding wafer W for manufacturing the light-emitting driving device package apparatus 100 according to embodiments of the present disclosure, the sapphire wafer W1 may include a wafer body B made of sapphire material, a plurality of devices D provided on the wafer body B and including light-emitters 11 for outputting light, thermal deformation prevention holes 30 provided between the devices D to prevent warping or distortion caused by thermal expansion coefficients when bonded to another wafer made of a different material, and aligners provided between the devices D to align bonding positions when bonded to another wafer.

Herein, the thermal deformation prevention holes 30 may include one or more long holes 30a (see FIGS. 1 to 3) penetrating through the wafer body B, extending in a lengthwise direction to counteract lateral thermal deformation forces, and having rounded inner surfaces 30b (see FIGS. 1 to 3) at both ends to prevent stress concentration at the ends, and the aligners 40 may include L-shaped or cross-shaped alignment protrusions T.

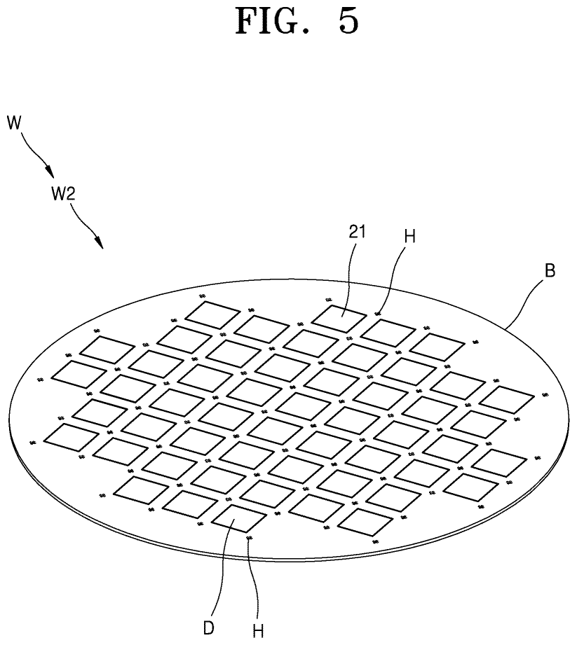

FIG. 5 is a perspective view of a silicon wafer W2 for manufacturing the light-emitting driving device package apparatus 100 of FIG. 1.

As shown in FIG. 5, as a bonding wafer W for manufacturing the light-emitting driving device package apparatus 100 according to embodiments of the present disclosure, the silicon wafer W2 may include a wafer body B made of silicon material, a plurality of devices D provided on the wafer body B and including driving circuits 21 for applying driving signals to the light-emitters 11, and aligners 40 provided between the devices D to align bonding positions when bonded to another wafer.

Herein, the aligners 40 may include L-shaped or cross-shaped alignment recesses H.

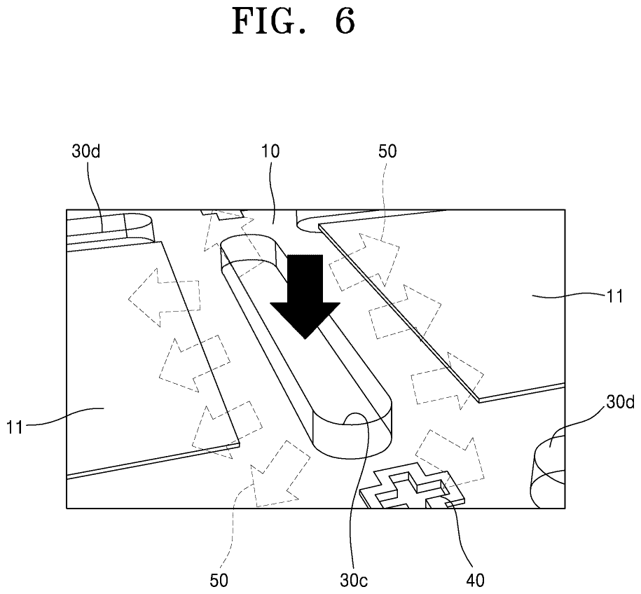

FIG. 6 is an enlarged perspective view showing a process of injecting the underfill 50 into the light-emitting driving device package apparatus 100 of FIG. 1.

As shown in FIG. 6, the thermal deformation prevention holes may be used not only to prevent thermal deformation but also to inject the underfill 50.

Therefore, at least one of the thermal deformation prevention holes 30 may serve as an injection port 30c through which the underfill 50 is injected, and at least another one of the thermal deformation prevention holes 30 may serve as a discharge port 30d through which the underfill 50 or internal air is discharged.

Accordingly, using the thermal deformation prevention holes 30, product durability and strength may be significantly increased by removing internal voids through repeated vacuuming and injection.

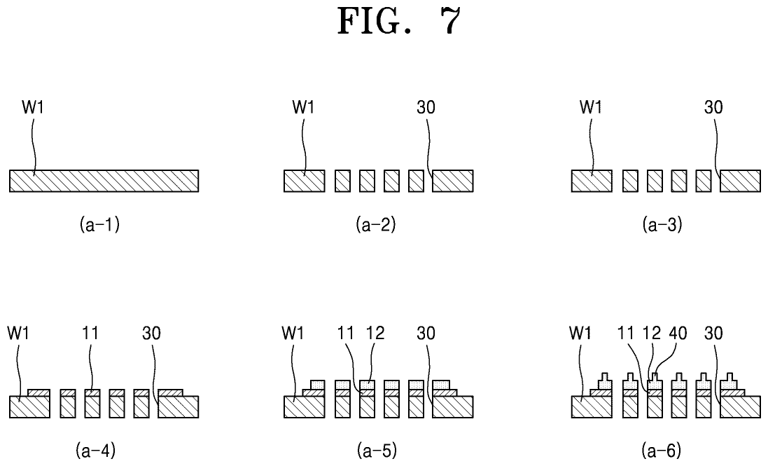

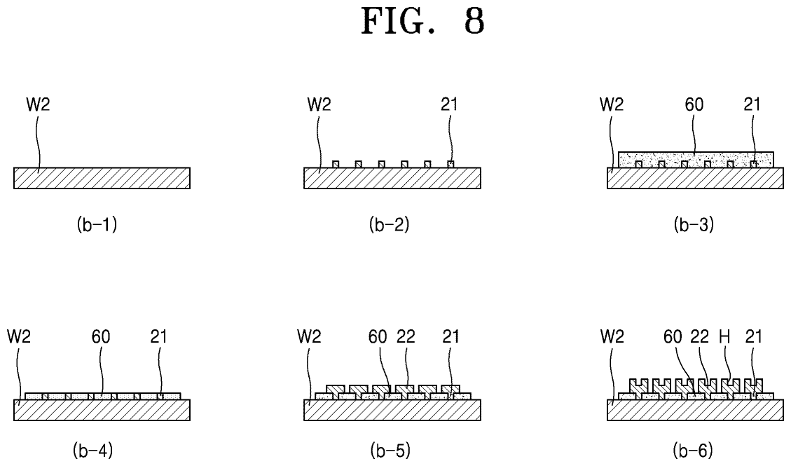

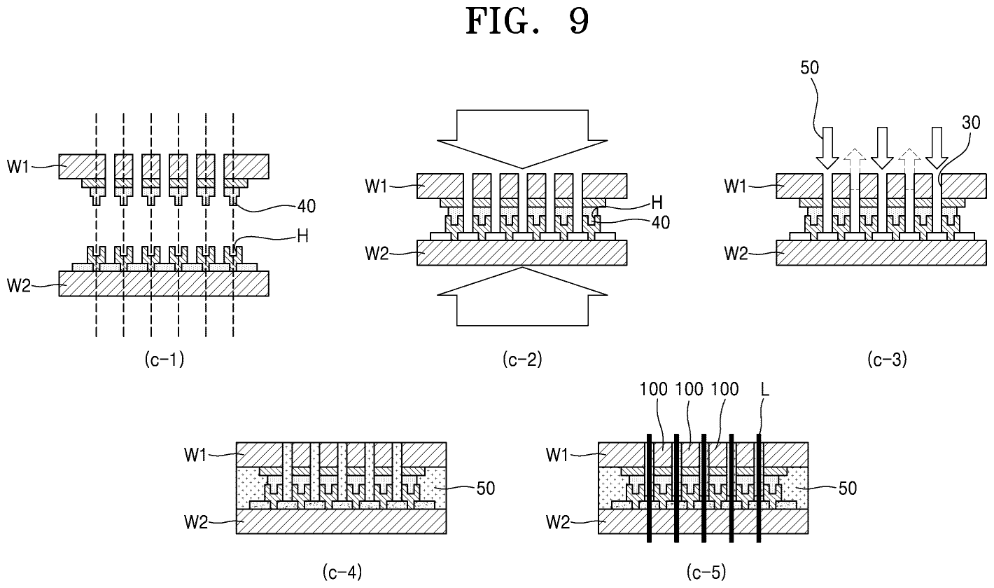

FIG. 7 includes cross-sectional views showing a process of preparing the sapphire wafer W1 of the light-emitting driving device package apparatus 100 of FIG. 4, step by step, FIG. 8 includes cross-sectional views showing a process of preparing the silicon wafer W2 of the light-emitting driving device package apparatus 100 of FIG. 5, step by step, and FIG. 9 includes cross-sectional views showing a process of bonding the sapphire wafer W1 of FIG. 4 to the silicon wafer W2 of FIG. 5, step by step.

As shown in FIGS. 7 to 9, a process of manufacturing the light-emitting driving device package apparatus 100 according to embodiments of the present disclosure will now be described step by step. Initially, as shown in FIG. 7, a sapphire wafer W1 made of sapphire material and including a plurality of light-emitting devices 10 with light-emitters 11 for outputting light may be prepared.

For example, a sapphire wafer W1 made of sapphire material may be provided as shown in (a-1), and thermal deformation prevention holes 30 may be formed using various methods such as etching or laser drilling as shown in (a-2).

Subsequently, the upper and lower surfaces may be ground as shown in (a-3), light-emitters 11 may be formed to emit light as shown in (a-4), and then connection terminals 12 such as bumps or pads may be formed on the light-emitters 11 as shown in (a-5). Thereafter, protrusion-shaped aligners 40 may be formed on the upper surfaces of the connection terminals 12 or on desired positions as shown in (a-6).

Meanwhile, as shown in FIG. 8, a silicon wafer W2 made of silicon material and including a plurality of driving devices 20 with driving circuits 21 capable of applying driving signals to the light-emitters 11 to drive the light-emitters 11 may be prepared.

For example, a silicon wafer W2 made of silicon material may be provided as shown in (b-1), and driving circuits 21 may be formed as shown in (b-2). Thereafter, an insulating member 60 may be formed on the driving circuits 21 as shown in (b-3), and then etched to expose the driving circuits 21 as shown in (b-4).

Subsequently, connection terminals 22 such as bumps or pads may be formed on the exposed driving circuits 21 as shown in (b-5), and then recess-shaped alignment recesses H may be formed in the upper surfaces of the connection terminals 22 or in desired positions as shown in (b-6).

After that, as shown in FIG. 9, the prepared sapphire wafer W1 and silicon wafer W2 may be bonded together, and the bonded sapphire wafer W1 and silicon wafer W2 may be cut into individual packages along scribe lines L.

For example, the sapphire wafer W1 and the silicon wafer W2 may be aligned to fit the aligners 40 into the alignment recesses H as shown in (c-1), and then the sapphire wafer W1 and the silicon wafer W2 may be bonded together as shown in (c-2).

Subsequently, the underfill 50 may be filled between the bonded sapphire wafer W1 and silicon wafer W2 by using the thermal deformation prevention holes 30 as shown in (c-3).

Thereafter, the underfill 50 may be cured in a high-temperature environment such as an oven as shown in (c-4), and then the bonded sapphire wafer W1 and silicon wafer W2 may be cut into individual packages along scribe lines L as shown in (c-5).

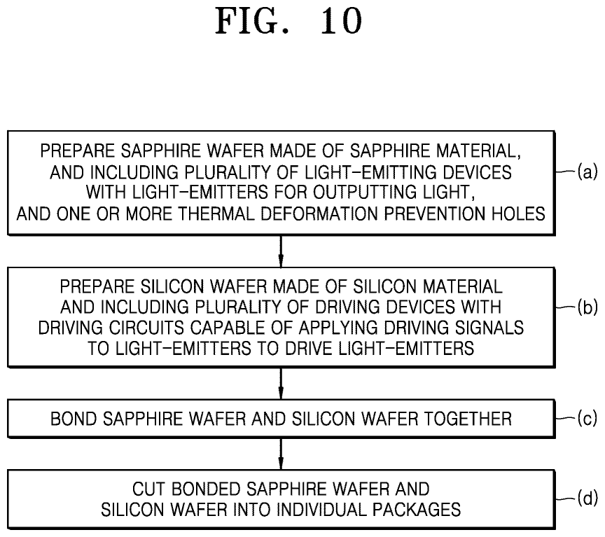

FIG. 10 is a flowchart of a method of manufacturing a light-emitting driving device package apparatus, according to embodiments of the present disclosure.

As shown in FIGS. 1 to 10, the method according to embodiments of the present disclosure may include (a) preparing a sapphire wafer W1 made of sapphire material and including a plurality of light-emitting devices 10 with light-emitters 11 for outputting light, (b) preparing a silicon wafer W2 made of silicon material and including a plurality of driving devices 20 with driving circuits 21 capable of applying driving signals to the light-emitters 11 to drive the light-emitters 11, (c) bonding the sapphire wafer W1 and the silicon wafer W2 together, and (d) cutting the bonded sapphire wafer W1 and silicon wafer W2 into individual packages along scribe lines L, wherein, in step (a) or step (b), one or more thermal deformation prevention holes 30 are formed in at least portions of the sapphire wafer W1 or the silicon wafer W2 to prevent warping or distortion caused by the difference in thermal expansion coefficient between sapphire material and silicon material.

In step (c), underfill 50 may be filled through the thermal deformation prevention holes 30 formed in one of the bonded wafers.

In step (a) or step (b), aligners 40 fitted to each other to align bonding positions when the sapphire wafer W1 and the silicon wafer W2 are bonded together may be formed on at least portions of the sapphire wafer W1 or the silicon wafer W2.

Therefore, according to the present disclosure, warping, distortion, cracks, or the like caused by the difference in thermal expansion coefficient when the sapphire wafer W1 and the silicon wafer W2 are bonded together may be prevented using the thermal deformation prevention holes 30. Because the underfill 50 may be injected through the thermal deformation prevention holes 30, product strength and durability may be significantly increased. The wafers may be bonded together by aligning them using the aligners 40. In addition, the diameter of the wafers may be increased, thereby significantly improving both yield and productivity and enabling mass production.

According to the afore-described embodiments of the present disclosure, warping, distortion, cracks, or the like caused by the difference in thermal expansion coefficient when a sapphire wafer and a silicon wafer are bonded together may be prevented using thermal deformation prevention holes. Because underfill may be injected through the thermal deformation prevention holes, product strength and durability may be significantly increased. The wafers may be bonded together by aligning them using the aligners. In addition, the diameter of the wafers may be increased, thereby significantly improving both yield and productivity and enabling mass production. However, the scope of the present disclosure is not limited to the above effects.

While the present disclosure has been particularly shown and described with reference to embodiments thereof, it will be understood by one of ordinary skill in the art that various changes in form and details may be made therein without departing from the scope of the present disclosure as defined by the following claims.

What is claimed is:

1. A light-emitting driving device package apparatus comprising:
a light-emitting device made of sapphire material and comprising a light-emitter for outputting light; and
a driving device bonded to the light-emitting device, made of silicon material, and comprising a driving circuit for applying a driving signal to the light-emitter to drive the light-emitter,
wherein thermal deformation prevention holes are formed in at least portions of the light-emitting device or the driving device to prevent warping or distortion caused by a difference in thermal expansion coefficient between sapphire material and silicon material.

2. The light-emitting driving device package apparatus of claim 1, wherein each thermal deformation prevention hole comprises at least a portion of a long hole extending along a side surface in a lengthwise direction to counteract lateral thermal deformation forces, and has rounded inner surfaces at both ends to prevent stress concentration at the ends.

3. The light-emitting driving device package apparatus of claim 2, wherein the thermal deformation prevention holes comprise:
a first long hole formed in a central portion of a first side surface of the light-emitting device;
a second long hole formed in a central portion of a second side surface of the light-emitting device;
a third long hole formed in a central portion of a third side surface of the light-emitting device; and
a fourth long hole formed in a central portion of a fourth side surface of the light-emitting device.

4. The light-emitting driving device package apparatus of claim 3, wherein at least one of the first, second, third, and fourth long holes serves as an injection port through which underfill is injected, and at least another one of the first, second, third, and fourth long holes serves as a discharge port through which the underfill or internal air is discharged.

5. The light-emitting driving device package apparatus of claim 3, further comprising aligners provided between the light-emitting device and the driving device and fitted to each other to align bonding positions when the light-emitting device and the driving device are bonded together.

6. The light-emitting driving device package apparatus of claim 5, wherein the aligners comprise:
a first alignment protrusion provided on a first corner of the light-emitting device or the driving device;
a second alignment protrusion provided on a second corner of the light-emitting device or the driving device;
a third alignment protrusion provided on a third corner of the light-emitting device or the driving device; and
a fourth alignment protrusion provided on a fourth corner of the light-emitting device or the driving device.

7. The light-emitting driving device package apparatus of claim 6, wherein the first alignment protrusion is L-shaped or cross-shaped.

8. A method of manufacturing a light-emitting driving device package apparatus, the method comprising:
(a) preparing a sapphire wafer made of sapphire material and comprising a plurality of light-emitting devices with light-emitters for outputting light;
(b) preparing a silicon wafer made of silicon material and comprising a plurality of driving devices with driving circuits capable of applying driving signals to the light-emitters to drive the light-emitters;
(c) bonding the sapphire wafer and the silicon wafer together; and
(d) cutting the bonded sapphire wafer and silicon wafer into individual packages,
wherein, in step (a) or step (b), one or more thermal deformation prevention holes are formed in at least portions of the sapphire wafer or the silicon wafer to prevent warping or distortion caused by a difference in thermal expansion coefficient between sapphire material and silicon material.

9. The method of claim 8, wherein, in step (c), underfill is filled through the thermal deformation prevention holes formed in one of the bonded wafers.

10. The method of claim 8, wherein, in step (a) or step (b), aligners fitted to each other to align bonding positions when the sapphire wafer and the silicon wafer are bonded together are formed on at least portions of the sapphire wafer or the silicon wafer.

11. A bonding wafer comprising:
a wafer body made of sapphire material or silicon material;
a plurality of devices provided on the wafer body and comprising light-emitters for outputting light, or driving circuits for applying driving signals to the light-emitters;
thermal deformation prevention holes provided between the devices to prevent warping or distortion caused by thermal expansion coefficients when bonded to another wafer made of a different material; and
aligners provided between the devices to align bonding positions when bonded to another wafer.

12. The bonding wafer of claim 11, wherein the thermal deformation prevention holes comprise one or more long holes penetrating through the wafer body, extending in a lengthwise direction to counteract lateral thermal deformation forces, and having rounded inner surfaces at both ends to prevent stress concentration at the ends, and
wherein the aligners comprise L-shaped or cross-shaped alignment protrusions.
